(19) United States
(12) Patent Application Publication
(10) Pub. No.: US 2003/0192007 A1
(43) Pub. Date: Oct. 9, 2003

(54) Code-programmable field-programmable architecturally-systolic Reed-Solomon BCH error correction decoder integrated circuit and error correction decoding method

(76) Inventors: David H. Miller, Sacramento, CA (US); Norman L. Swenson, Mountain View, CA (US); Hari Surapaneni, Los Altos Hills, CA (US); Richard W. Koralek, Palo Alto, CA (US); James M. Gardner, San Ramon, CA (US)

Correspondence Address: Keith D. Nelson, Lockheed Martin Corporation, Building 220, Mail Stop A08, P.O. Box 49041, San Jose, CA, 95161-9041, US

(21) Appl. No.: 09/838,610

(22) Filed: Apr. 19, 2001

(51) Int. Cl. H03M 13/00

(52) U.S. Cl. 714/782

(57) ABSTRACT

A programmable error-correction decoder embodied in an integrated circuit and error correction decoding method that performs high-speed error correction for digital communication channels and digital data storage applications. The decoder carries out error detection and correction for digital data in a variety of data transmission and storage applications. The decoder has three basic modules, including a syndrome computation module, a Berlekamp-Massey computation module, and a Chien-Forney module. The syndrome computation module calculates syndromes which are intermediate values required to find error locations and values. The Berlekamp-Massey module implements a Berlekamp-Massey algorithm that converts the syndromes to intermediate results known as lambda (Λ) and omega (Ω) polynomials. The Chien-Forney module uses modified Chien-search and Forney algorithms to calculate actual error locations and error values. The decoder can decode a range of BCH and Reed-Solomon codes and shortened versions of these codes and can switch between these codes, and between different block lengths, while operating on the fly without any delay between adjacent blocks of data that use different codes. Translator and inverse-translator circuits are employed that allow optimal choice of the internal on-chip Galois field representation for maximizing chip speed and minimizing chip gate count by making possible the use of a novel quadratic-subfield modular multiplier and a novel power-subfield integrated Galois-field divider. A simplified Chien-Forney algorithm is implemented that requires fewer computations to determine error magnitudes for Reed-Solomon codes with offsets compared to conventional approaches, and which allows the same circuitry to be used for different codes with arbitrary offsets.

### BACKGROUND

The present invention relates generally to error correction decoders and decoding methods, and more particularly, to a programmable, architecturally-systolic, Reed-Solomon, Bose-Chaudhuri-Hocquenghem (BCH) error correction decoder that is implemented in the form of an integrated circuit and error correction decoding method.

The closest previously known solutions to the problem addressed by the present invention are disclosed in U.S. Pat. No. 5,659,557 entitled “Reed-Solomon code system employing k-bit serial techniques for encoding and burst error trapping”, U.S. Pat. No. 5,396,502 entitled “Single-stack implementation of a Reed-Solomon encoder/decoder”, U.S. Pat. No. 5,170,399 entitled “Reed-Solomon Euclid algorithm decoder having a process configurable Euclid stack”, and U.S. Pat. No. 4,873,688 entitled “High-speed real-time Reed-Solomon decoder”.

U.S. Pat. No. 5,659,557 discloses apparatus and methods for providing an improved system for encoding and decoding of Reed-Solomon and related codes. The system employs a k-bit-serial shift register for encoding and residue generation. For decoding, a residue is generated as data is read. Single-burst errors are corrected in real time by a k-bit-serial burst trapping decoder that operates on the residue. Error cases greater than a single burst are corrected with a non-real-time firmware decoder, which retrieves the residue and converts it to a remainder, then converts the remainder to syndromes, and then attempts to compute error locations and values from the syndromes. In the preferred embodiment, a new low-order first, k-bit-serial, finite-field constant multiplier is employed within the burst trapping circuit. Also, code symbol sizes are supported that need not equal the information byte size. Time-efficient or space-efficient firmware for multiple-burst correction may be selected.

U.S. Pat. No. 5,396,502 discloses an error correction unit (ECU) that uses a single stack architecture for generation, reduction and evaluation of polynomials involved in the correction of a Reed-Solomon code. The circuit uses the same hardware to generate syndromes, reduce (x) and (x) polynomials and evaluate the (x) and (x) polynomials. The implementation of the general Galois field multiplier is faster than previous implementations. The circuit for implementing the Galois field inverse function is not used in prior art designs. A method of generating the (x) and (x) polynomials (including alignment of these polynomials prior to evaluation) is utilized. Corrections are performed in the same order as they are received using a premultiplication step prior to evaluation. A method of implementing flags for uncorrectable errors is used. The ECU is data driven in that nothing happens if no data is present. Also, interleaved data is handled internally to the chip.

U.S. Pat. No. 5,170,399 discloses a Reed-Solomon Galois field Euclid algorithm error correction decoder that solves Euclid's algorithm with a Euclid stack that can be configured to function as a Euclid divide or a Euclid multiply module. The decoder is able to resolve twice the erasure errors by selecting (x) and T(x) as initial conditions for (O)(x) and (O)(x), respectively.

U.S. Pat. No. 4,873,688 discloses a Galois field error correction decoder that can correct an error in a received polynomial. The decoder generates a plurality of syndrome polynomials. A magnitude polynomial and a location polynomial having a first derivative are calculated from the syndrome polynomials utilizing Euclid's algorithm. The module utilizing Euclid's algorithm includes a general Galois field multiplier having combinational logic circuits. The magnitude polynomial is divided by a first derivative of the location polynomial to form a quotient. Preferably, the division includes finding the inverse of the first derivative and multiplying the inverse by the magnitude polynomial. The error is corrected by exclusive ORing the quotient with the received polynomial.

However, known prior art approaches do not have an architecturally-systolic design that makes possible instantaneous switching “on the fly” among a large number of codes. Also, known prior art approaches do not allow programmability among a wide variety of alternative codes using different Galois-field representations. Prior art approaches do not employ a Chien-Forney implementation that allows changes in code “offset” and “skip” values to be implemented solely through gate-array changes in exclusive-OR trees in syndrome and Chien-Forney modules. Furthermore, prior art approaches do not use an optimized on-chip subfield representation, a power sub-field divider, parallel quadratic-subfield modular multipliers, or an improved Chien-Forney algorithm that provides for superior speed/gate-count trade-off.

Accordingly, it is an objective of the present invention to provide for a programmable, architecturally-systolic, Reed-Solomon BCH error correction decoder that is implemented in the form of an integrated circuit along with a corresponding error correction decoding method.

### SUMMARY OF THE INVENTION

To accomplish the above and other objectives, the present invention provides for a programmable error-correction decoder embodied in an integrated circuit and error correction decoding method that performs high-speed error correction for digital communication channels and digital data storage applications. The decoder carries out error detection and correction for digital data in a variety of data transmission and storage applications. Error-correction coding provided by the decoder reduces the amount of transmission power and/or bandwidth required to support a specified error-rate performance in communication systems and increases storage density in data storage systems.

The error correction decoder comprises three basic modules, including a syndrome computation module, a Berlekamp-Massey computation module, and a Chien-Forney module. The syndrome computation module calculates quantities known as “syndromes” which are intermediate values required to find error locations and values. The Berlekamp-Massey computation module implements a Berlekamp-Massey algorithm that converts the syndromes to other intermediate results known as lambda (Λ) and omega (Ω) polynomials. The Chien-Forney module uses modified Chien-search and Forney algorithms to calculate actual error locations and error values.

The decoder is embodied in an integrated circuit that can decode a range of BCH and Reed-Solomon codes as well as shortened versions of these codes and can switch between these codes, and between different block lengths, while operating “on the fly” without any delay between adjacent blocks of data that use different codes. Translator and inverse-translator circuits are employed that allow optimal choice of the internal on-chip Galois field representation for maximizing chip speed and minimizing chip gate count. A simplified Chien-Forney algorithm is implemented that requires fewer computations to determine error magnitudes for Reed-Solomon codes with code-generator-polynomial offsets compared to conventional approaches, and which allows the same circuitry to be used for different codes with arbitrary offsets in the code generator polynomial, unlike conventional approaches.

An architecturally-systolic design is implemented among different chip modules so that the different modules can have separate asynchronous clocks and so that configuration information travels with the data from module to module: configuration information is carried with the data and makes possible on-the-fly switching among different codes. A novel “power-subfield” algorithm and circuit are used to carry out Galois-field division. A massively parallel multiplier array employing quadratic-subfield modular multipliers is used in the Berlekamp-Massey module. Dual-mode operation for BCH codes allows two simultaneous BCH data blocks to be processed. Internal registers and computation circuitry are shared among different types (binary BCH and non-binary Reed-Solomon) to reduce the gate count of the integrated circuit.

The massively parallel multiplier structure in the Berlekamp-Massey module is independent of the subfield field representation. It is to be understood that this architecture, in which the Berlekamp-Massey module uses a relatively large number of multipliers in parallel, may be used with a decoder using conventional field representation and conventional textbook Galois Field multipliers.

The decoder is highly programmable. The integrated circuit embodying the decoder has an extraordinary degree of flexibility in the error correction codes it can handle and in ease of switching among these modes. Furthermore, the decoder is designed in such a way that straightforward alternative implementations can extend this programmability quite dramatically

More specifically, the decoder can decode ten different Reed-Solomon and BCH codes and may be easily modified to handle an additional seventeen codes. The decoder can switch on the fly with no delay whatsoever among these different codes. The decoder can also handle a wide variety of shortened codes based on the ten basic codes and can switch on the fly with no delay among different degrees of shortening.

In one of its most unusual features, the decoder uses a different mathematical representation internally from that used off-chip for the “Galois field”, which is a mathematical structure used in error-correction systems. The importance of this feature is that it makes it possible to easily handle incoming data which may be expressed in a different Galois-field representation from that used internally on the chip, either by minor changes at the gate array level or, in an alternative implementation, by providing programmability on the chip for different representations; furthermore, this feature make it possible to choose the representation used on-chip independently of that used for the incoming data so as to optimize speed and gate-count for the chip, specifically by using a novel quadratic-subfield modular multiplier circuit and a novel power-subfield integrated Galois-field division circuit on the chip.

The integrated circuit chip embodying the decoder has an “architecturally-systolic” structure. To maximize speed, data throughput, and ease of use in applications, the decoder and integrated circuit chip have been designed to adhere to an “architecturally-systolic” philosophy. The structure is not systolic at the logic-gate level, but the relationship among the three primary modules of the decoder demonstrates systolic-like behavior. Specifically, clocks for the different modules are independently free-running and asynchronous with no specified phase relationship, which allows maximal speed to be attained for each module. Furthermore, transfer of data, control, and code identification information is handled among the three modules internally without any control from off-chip. It is this internal transfer structure which makes possible no-delay switching among codes and among different degrees of shortening.

In addition, the decoder uses a novel circuit to perform “Forney's algorithm” which makes possible programmability among different code polynomials: this Chien-Forney module allows a further degree of programmability, involving the “code-generator polynomial” that may also easily be introduced into the decoder at the gate array level or with on-chip programmability. A dual-mode BCH configuration is also implemented that can handle two parallel BCH code words at once.

A massively parallel Galois-field multiplier structure is used in the Berlekamp-Massey module: this multiplier structure is feasible because of the use of novel quadratic-subfield modular multipliers made possible by the use of a quadratic-subfield representation on the chip. Readout and test capabilities are provided.

A reduced-to-practice embodiment of the decoder has been fabricated as a CMOS gate array but may be easily implemented using gallium arsenide or other semiconductor technologies.

The “architecturally-systolic” design of the decoder provides for instantaneous switching on the fly among a large number of codes, unlike prior art approaches. The ability to use a different Galois-field representation off-chip than on-chip allows programmability of the design among a wide variety of alternative codes using different Galois-field representations. The Chien-Forney implementation allows changes in “code offset” and “skip” values to be implemented solely through gate-array changes in exclusive-OR trees in syndrome and Chien-Forney modules. The use of optimized on-chip subfield representation. power-subfield divider, massively parallel quadratic-subfield modular multipliers, and improved Chien-Forney algorithm allows superior speed/gate-count trade-off compared to prior art approaches.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 is a block diagram illustrating the architecture of a programmable, systolic, Reed-Solomon BCH error correction decoder in accordance with the principles of the present invention;

FIG. 2 is a block diagram illustrating a full error correction system making use of the present invention; and

FIGS. 3 through 10 illustrate details of modules shown in FIGS. 1 and 2.

### DETAILED DESCRIPTION

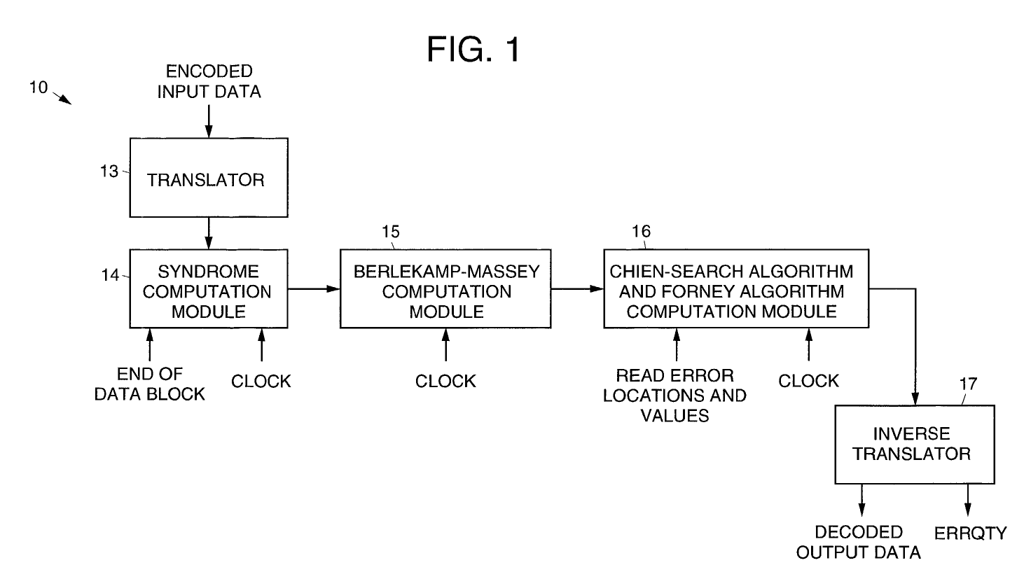

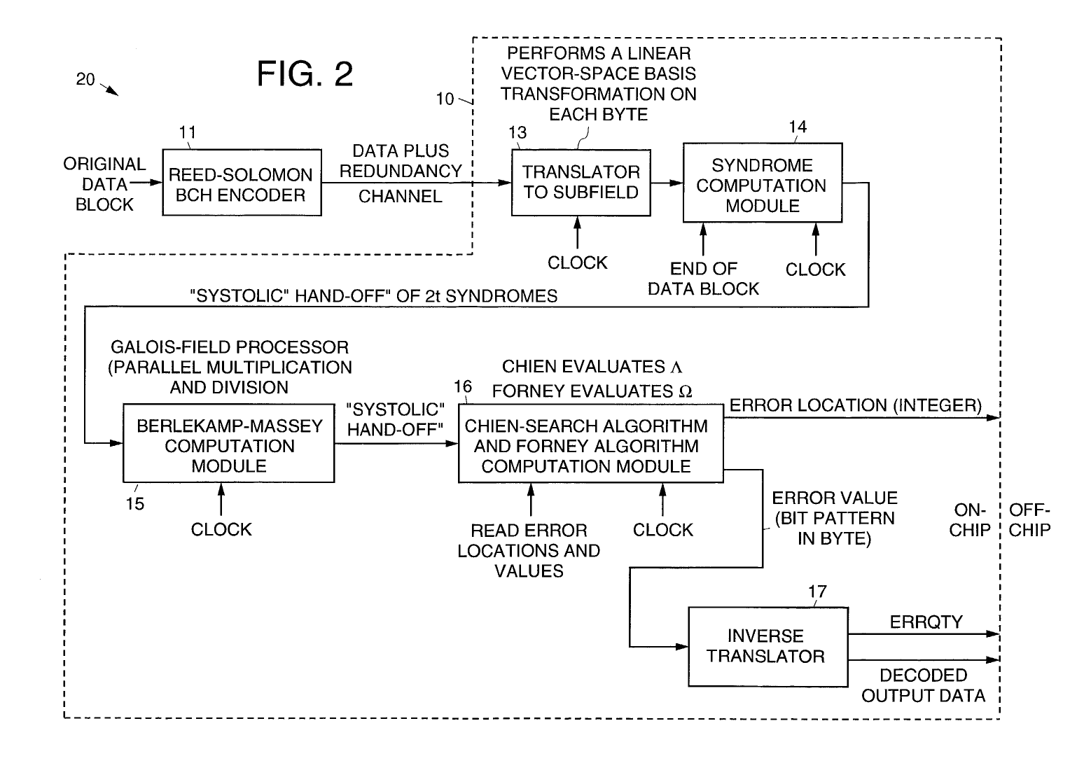

Referring to the drawing figures, FIG. 1 is a block diagram illustrating the architecture of a programmable, architecturally-systolic, Reed-Solomon BCH error correction decoder 10 in accordance with the principles of the present invention. The programmable, architecturally-systolic, Reed-Solomon BCH error correction decoder 10 is embodied in an integrated circuit. FIG. 2 is a block diagram illustrating a full error correction system 20 making use of the error correction decoder 10.

Referring to FIG. 1, the decoder 10 includes a subfield translator 13 that processes encoded input data to perform a linear vector-space basis transformation on each byte of the data. The subfield translator 13 is coupled to a syndrome computation module 14 which performs parity checks on the transformed data and outputs 2t syndromes. The syndrome computation module 14 is coupled to a Berlekamp-Massey computation module 15 that implements a Galois-field processor comprising a parallel multiplier and a divider that converts the syndromes into lambda (Λ) and omega (Ω) polynomials. The Berlekamp-Massey computation module 15 is coupled to a Chien-Forney module 16 that calculates error locations and error values from the polynomials and outputs them. An inverse translator 17 performs an inverse linear vector-space basis transformation on each byte of the calculated error values.

Referring to FIG. 2, an original data block is encoded by a Reed-Solomon BCH encoder 11, not part of the current invention, which outputs data over a channel to a Reed-Solomon decoder 10 which decodes the Reed-Solomon encoding. The subfield translator 13 performs a linear vector-space basis transformation on each byte of the data. The syndrome computation module 14 performs parity checks on the transformed data and outputs syndromes. The Berlekamp-Massey computation module 15 (Galois-field processor) converts the syndromes into lambda (Λ) and omega (Ω) polynomials. The Chien-Forney module 16 uses a Chien algorithm to calculate error locations and error values from the polynomials and outputs them. The Chien algorithm evaluates the lambda (Λ) polynomials while the Forney algorithm uses both the lambda (Λ) and the omega (Ω) polynomials to calculate the actual bit pattern within a byte that corresponds to the error value. The inverse translator 17 performs an inverse transform on each byte of the calculated error values to translate between the internal chip Galois-field representation and the external representation that is output from the decoder 10.

Thus, the error correction decoder 10 comprises three basic modules, including the syndrome computation module 14, the Berlekamp-Massey computation module 15, and the Chien-Forney module 16. The syndrome computation module 14 calculates quantities known as “syndromes” which are intermediate values required to find error locations and values. The Berlekamp-Massey computation module 15 implements a Berlekamp-Massey algorithm that converts the syndromes to other intermediate results known as lambda (Λ) and omega (Ω) polynomials. The Chien-Forney module 16 uses modified Chien-search and Forney algorithms to calculate the actual error locations and error values.

The error correction decoder 10 is implemented as a high-speed integrated circuit capable of error-detection and error-correction in digital data transmission and storage applications including, but not limited to, microwave satellite communications systems. Use of error correction technology reduces the power and/or bandwidth required to support a specified error-rate performance under given operating conditions in data transmission systems: in data storage systems, error correction technology makes possible higher storage densities.

A reduced-to-practice embodiment of the error correction decoder 10 has been designed to decode six different Reed-Solomon codes and four different BCH codes. Reed-Solomon and BCH codes are “block codes” which means that the data is, for error-correction purposes, processed in blocks of a given maximum size. In the encoder 11, each block of data has a number of redundancy symbols appended to it. The present decoder 10 processes the total block (data and redundancy symbols) and attempts to detect and correct errors in the block. These errors can arise from a variety of sources depending on the application and on the transmission or storage medium.

In standard notation, the Reed-Solomon codes that can be decoded by the present decoder 10 are: (255, 245) t=5, (255, 239) t=8, (255, 235) t=10, (255, 231) t=12, (255, 229) t=13, and (255, 223) t=16. Here, as is well-known in the field, “t” is the number of errors the code is guaranteed to be capable of correcting within a single block of data-plus-redundancy. Standard (n, k) notation is used to denote the code, where n is the number of symbols of data plus redundancy in one code block and k is the number of symbols of data alone. Therefore, the (255, 245) code has 245 symbols of data and 10 additional redundancy symbols. For all six of these particular Reed-Solomon codes, a single symbol is one byte (i.e., eight bits).

For Reed-Solomon codes, a symbol is treated both in mathematical analysis and physically by the decoder (chip) 10 as a single unit, and hence the decoder 10 processes Reed-Solomon data byte-wide. The BCH codes that the decoder 10 can decode are: (255, 231) (255, 230), (255, 223), and (255, 171), again using the (n, k) notation. For BCH codes, a symbol includes one bit. This specific choice of codes is unique to the decoder 10.

In an alternative implementation which involves only minor changes to input and control registers, the decoder 10 is capable of decoding Reed-Solomon codes with all t-values up to t=16 and BCH codes with all t-values up to t=11. These changes include a chip programming interface, because t values are loaded into the decoder 10, a grand loop counter in the Berlekamp-Massey module 15, and changes to steering circuitry that selects which syndromes to use. Further changes to the syndrome module 14 (adding additional exclusive-OR trees) extend the capability to decode BCH codes up to t=16.

The decoder 10 can switch “on-the-fly” during operation, between different codes, which is a significant feature of the invention. To enable immediately succeeding code words to be from different codes, a configuration word is loaded for each code word, and that configuration word follows the code word from the syndrome module 14 to the Berlekamp-Massey module 15 and onward to the Chien-Forney module 16. This aspect of the decoder 10 is a separate and distinct feature compared to the ability of the decoder 10 to switch between codes of different degrees of shortening on the fly.

The reduced-to-practice embodiment of the decoder 10 was implemented in a CMOS gate array. However, it is completely straightforward to implement the decoder 10 using any standard semiconductor technology, including, but not limited to, gallium arsenide gate arrays, or gallium arsenide custom chips.

Using the (n, k) notation, an (n, k) code, whether Reed-Solomon or BCH, can easily be used as an (n−i, k−i) code for any positive i less than k. The decoder 10 may be used in this way to handle such “shortened” codes. Control signals are used so that the value of i can be adjusted on the fly without any delay between data blocks that have been shortened by different amounts. The only constraint is that there must be enough time for the decoder 10 to process one data block before receiving the next block.

Specifically, the block length is controlled by a signal bit that goes high when the first byte arrives and goes low at the last byte. An internal counter (not shown) counts the number of bytes, and the falling edge of this signal indicates that the block is complete and the byte counter now contains the block length. The ability to use shortened codes and to switch on the fly between shortened codes of different degrees of shortening is a separate and independent feature of the decoder 10, which is different from the ability to switch between codes of different t values. This is a significant and useful feature of the decoder 10.

As mentioned above, the decoder 10 is divided into three basic modules. The syndrome module 14 calculates syndromes which are intermediate values required to find error locations and values. The Berlekamp-Massey module 15 implements an algorithm universally known as a Berlekamp-Massey algorithm that converts the syndromes to other intermediate results known as lambda and omega polynomials. The Chien-Forney module 16 uses modified Chien-search and Forney algorithms to calculate actual error locations and error values.

The speed of the clock of each of these three modules 14, 15, 16 can be independently controlled separately from the other two modules, and there is no required phase relationship among the clocks for the different modules 14, 15, 16. Thus, the clocks for the separate modules 14, 15, 16 can be free-running (the clocks for the different modules 14, 15, 16 may also be tied together if desired). This allows optimum speed and performance for the decoder 10 and flexibility. This is a significant feature of the decoder 10. The clocks for the different modules 14, 15, 16 may also be tied together off-chip if desired.

Furthermore, while an off-chip signal tells the syndrome module 14 that the end of a data block has occurred and off-chip signals tell the Chien-Forney module 16 to read out error locations and values, all timing of data transfer and transfer of control among the three modules 14, 15, 16 is asynchronously controlled internally on-chip without any control from off-chip circuits.

Because the time required for each module to complete its task is variable, depending on number of errors, degree of shortening, etc., and because these factors commonly do differ between one block of data and the immediately following block, and because the clocks for different modules can run independently which alters the actual elapsed time required for each module 14, 15, 16 to perform its task, this flexible internal control of transfers between modules is very important and can greatly ease the use of the decoder 10 in applications.

This feature of the decoder 10 is separate and distinct from the feature which allows separate asynchronous clocks for the different modules 14, 15, 16. That is to say, the decoder 10 may use on-chip data flow but not use separate free-running clocks, or vice versa. This asynchronous-internally-controlled transfer of data and control among the modules 14, 15, 16 is a desirable feature of the present invention.

To carry out the mathematical calculations involved in decoding Reed-Solomon and BCH error-correction codes, mathematical structures known as “Galois fields” are employed. For a given-size symbol, there are a number of mathematically-isomorphic but calculationally distinct Galois fields. Specification of a Reed-Solomon code requires choosing not only values for n and k (in the (n, k) notation) but also choosing a Galois-field representation. Two Reed-Solomon codes with the same n and k values but different Galois-field representations are incompatible in the following sense: the same block of data will have different redundancy symbols in the different representations, and a circuit that decodes a Reed-Solomon code in one representation generally cannot decode a code using another Galois-field representation. This is not true for BCH codes.

From the viewpoint of a Reed-Solomon decoder 10, the Galois-field representation is commonly given by external constraints set in an encoder 11 in a transmitter for data transmission applications or in an encoder 11 in a write circuit for data storage applications. This normally precludes choosing a representation that will optimize the operations required internally in the decoder 10 to find the errors.

In the decoder 10, the externally given Galois-field representation is not in fact optimal for internal integrated circuit operations. Therefore, a different Galois-field representation is used on-chip than is used external to the chip. An internal representation was chosen by computer analysis to maximize global chip speed and, subject to speed maximization, to minimize global chip gate count. The translator circuit 13 is used at the front end of the decoder 10 and the inverse translator circuit 17 is used at the back end to translate between the internal chip Galois-field representation and the external representation.

The internal Galois-field representation is a “quadratic subfield” representation. Galois fields are finite mathematical structures that obey all of the normal algebraic rules obeyed by ordinary real numbers but with different addition and multiplication tables: these mathematical structures have numerous uses including error correction and detection technology.

Just as there are a number of different ways of representing ordinary numbers (decimal numbers, binary notation, Roman numerals, etc.), so also there are an infinite number of different ways of representing Galois fields. The most common technique represents elements of a Galois field by means of a so-called field-generator polynomial (not to be confused with the code-generator polynomial). The corresponding notation represents elements of the field by using the root of this field-generator polynomial as a base for the Galois-field number system, much as the number 10 is the base of the decimal system or the number 2 serves as the base of the binary system (in the case of Galois fields, this base element also serves as a natural base for integer-valued logarithms, which is not the case for ordinary numbers).

However, it has been known to mathematicians for over a century that there are other techniques for representing the elements of Galois fields. For example, the normal way of representing complex numbers uses ordered pairs of real numbers: since the real numbers are a complete field mathematically in and of themselves, the complex numbers are referred to as a field extension of the real numbers and the real numbers are referred to as a subfield of the complex numbers. The two components of a complex number differ by a factor of the square root of minus one, and in a sense this factor serves as a base element for the complex numbers over the real numbers. The real numbers can then still be placed in whatever representation one chooses (decimal, binary, etc.), so, in a sense, one has a double choice of field bases—first for the real numbers themselves and then to go from the real to the complex numbers.

The same technique works for many Galois fields. The smaller Galois field that plays the same role as the real numbers is the subfield. If the element that takes one from the subfield to the whole field (i.e., the square root of minus one for complex numbers) satisfies a quadratic equation with coefficients in the subfield, is referred to as a “quadratic subfield”. Real numbers are, in fact, a quadratic subfield of the complex numbers.

When a field is represented in a quadratic subfield representation, it always takes an ordered pair of subfield elements to represent an element of the whole field, just as an ordered pair of real numbers represents a single complex number. The processes of addition, multiplication, and division in Galois-field subfield representations are very similar to the same processes carried out in the usual ordered-pair representation of complex numbers.

All of this is classical mathematics more than a century old. Quadratic-subfield representations are not therefore in and of themselves a novelty. The novelty in the present invention lies rather in the invention of novel and greatly improved Galois-field multipliers and divider modules that are made possible by the use of a quadratic-subfield representation on-chip. These novel and powerful circuits, described in more detail below, work in the quadratic-subfield representation.

Given that the data coming into the decoder (chip) 10 are, in general, not in a quadratic-subfield representation (because this is generally not the preferred implementation for error-correction encoders), the advantages gained by using a quadratic-subfield representation on-chip are realized if the translator and inverse translator circuits 13, 17 are employed for incoming and outgoing data, respectively, to translate in and out of the subfield representation. Use of such translator and inverse translator circuits 13, 17 has the additional advantage that the decoder 10 can easily be modified at the gate-array level or, in an alternative implementation, programmed on-chip so as to accept data encoded in any standard field representation. This level of flexibility is an added benefit not available in conventional error-correction decoders.

An important feature of the decoder 10 is, therefore, that, by changing the translator and inverse-translator circuits 13, 17 at a gate-array level, all standard Galois-field representations can be processed for the external data and redundancy with no change of any sort in the chip except for the changes in the translator and inverse translator circuits 13, 17. This is in no way restricted to standard polynomial or subfield representations, but includes any representation that is linearly related to the standard representations, which includes but is not limited to all standard polynomial and subfield representations. The term “linearly” refers to the fact that a standard representation can be considered to be a vector space over the Galois field known as GF(2). This includes all currently used representations. This dramatically expands the number of systems in which the decoder 10 may be used. An alternative and straightforward implementation of the decoder 10 includes programmable translator and inverse-translator circuits 13, 17 internally on-the-fly on the chip rather than at the gate-array level. There are several well-known ways to do this.

The Berlekamp-Massey module 15 carries out repeated dot product calculations between vectors with up to seventeen components using Galois-field arithmetic. The usual textbook method of doing this is to have a single multiplication circuit as part of a Galois-field arithmetic logic unit (GFALU). Instead, in the decoder 10, seventeen parallel multipliers implemented in the Berlekamp-Massey module 15 are used to carry out the dot product in one step. This massive parallelism significantly increases speed, and is made feasible because of the optimizing choice of an internal quadratic-subfield Galois-field representation that is different from the representation used off-chip. The parallel multiplier circuit operating in an internal quadratic-subfield Galois-field representation is a novel feature of the present invention.

The massively parallel multiplier structure in the Berlekamp-Massey module is independent of the subfield field representation. This architecture of the Berlekamp-Massey module which uses a relatively large number of multipliers in parallel, may also be used with a decoder using conventional field representation and conventional textbook Galois Field multipliers.

The decoder 10 can process two simultaneous synchronous bit streams, each encoded with the same BCH code, for (255, 231), (255, 230), and (255, 223) BCH codes. Specifically, in this dual mode, the two data input signals correspond to what would be two LSB's of the input byte when the chip is decoding a Reed-Solomon code word. One of these two signals constitutes input data for one BCH code word and the other input signal contains data that makes up the second independent BCH code word. The two code words are decoded independently, and the resulting error locations are output separately. This feature can be useful in variations of QPSK modulation schemes, where I and Q channels are often coded separately, and in other advanced error-correction schemes in MPSK modulation systems and for other purposes.

Both the Berlekamp-Massey Galois-field ALU in the Berlekamp-Massey module 15 and the Forney algorithm section of the Chien-Forney module 16 require a circuit that rapidly carries out Galois-field division. The decoder 10 implements a novel power-subfield integrated Galois-field divider circuit 40 (FIG. 6) to perform this function which combines subfield and power methods of multiplicative inversion. The power-subfield Galois-field divider circuit 40 may be used in a wide variety of applications not limited to this chip or to Reed-Solomon and BCH codes, such as in algebraic-geometric coding systems, for example.

The Chien-Forney circuit 16 is used to implement the Forney algorithm for use with Read-Solomon codes with “offsets”. The Chien-Forney circuit 16 requires fewer stages for the calculation and can perform at higher speed than conventional Forney-algorithm circuits. The Chien-Forney circuit 16 may be used in a wide variety of applications not limited to the present decoder 10.

In an alternative implementation involving changes or programmability in XOR-trees in the syndrome module 14 and XOR trees in the Chien-Forney module 16, the decoder 10 may handle codes with different code-generator polynomials. Reed-Solomon codes are defined by a choice of the size of the code symbol (the size is one byte in the disclosed embodiment of the decoder 10), by the choice of the field-representation (which may be varied in the decoder 10 by altering the translator and inverse-translator circuits 13, 17), and by the choice of a specific code-generator polynomial (which is different from the field-generator polynomial). The code-generator polynomial is specified using an “offset” and a “skipping value” for the roots of the polynomial.

By using the Chien-Forney implementation embodied in the Chien-Forney module 16, a change in offset or skipping value for the generator polynomial can be handled solely by changing the XOR trees in the syndrome and Chien-Forney modules 14, 16 without any changes whatsoever in the Berlekamp-Massey module 15. Such changes in the XOR trees may be made by making changes in the gate array or by introducing further programmability into the syndrome and Chien-Forney modules 14, 16.

Typically, the construction of the Chien search algorithm causes error locations and values to naturally come out in a reverse order to the order in which the data flows through the decoder 10, which complicates correction of the errors. In the decoder 10, on the contrary, error locations and values come out in forward order to facilitate on-the-fly error correction.

In any error-correction system, a certain fraction of error patterns that cannot be corrected nonetheless “masquerade” as correctable error patterns. The masquerading error patterns are wrongly corrected, adding additional errors to the data. There are a large number of possible checks that can be carried out to detect uncorrectable error patterns, including, for example, checking that the leading order term of the output of the Berlekamp-Massey module (the lambda polynomial A) be non-zero. The present decoder 10 has been designed so as to detect all of the uncorrectable patterns in the Reed-Solomon codes which are mathematically detectable without carrying out most of these possible checks but only by combined use of a simple check in the Berlekamp-Massey module 15 (i.e., that the length of the lambda polynomial not exceed a given maximum) and another simple check in the Chien-Forney module 16 (i.e., that as many errors are actually found as indicated by the Berlekamp-Massey module 15). Thus, the fraction of uncorrectable patterns in the Reed-Solomon codes that “masquerade” as correctable patterns when using the decoder 10 is the absolute minimum that is mathematically allowed. The decoder 10 meets this theoretically optimal performance criterion.

In the syndrome module 14, syndrome registers used for the Reed-Solomon codes are re-used for the BCH codes. This requires switching between the exclusive-OR trees which are used in the syndrome module 14. Certain “trees” of exclusive-or (XOR) logic gates are required in both the syndrome and Chien-Forney modules 14, 16. In an alternative implementation of the decoder 10, these XOR trees and the accompanying registers that are used in the syndrome module 14 are also used in the Chien-search module 16. This alternative implementation may be used to minimize the area of the decoder integrated circuit, but this results in a significant reduction in the rate of data throughput.

For ease and flexibility in outputting final results, the output of the Chien-Forney module 16 is double-buffered. Double-buffering allows the error results from one code word to be read out while the chip is processing the next code word. Furthermore, this allows a fairly long time for the error results to be read out, thereby relaxing the requirements on external circuitry that reads the results. One output of the decoder 10 is ERRQTY, which is a signal indicative of the number of errors detected by the decoder 10 in a code block. The other outputs are the error location, which is an integer value indicative of the location (bit position) of the error, and the error value, which indicates the pattern of errors within one byte of data.

Repeated multiplies are carried out in the Berlekamp-Massey module 15, and in particular, the Galois-field ALU. For maximum speed of chip operation, it is necessary that a large number (17 in the disclosed embodiment) of multiplications be repeatedly carried out in parallel all at once. This can be done by use of a massive bank of parallel multipliers (17 parallel multipliers in the disclosed embodiment). Both the speed and the size of these multipliers is important because of the large number that are present.

There are several methods by which these Galois-field multiplications may be done. A random-logic multiply operation using the off-chip Galois field representation may be performed, which is relatively straightforward but requires a relatively large circuit. As an alternative, standard log and antilog tables may be employed, especially in a CMOS decoder 10. This approach requires separate log and antilog tables (each 256 by one byte for 255 codes). This approach also requires a mod 255 binary adder. Subfield log and antilog tables may be used, which requires much smaller (by about a factor of eight) tables. However, this approach requires complicated additional circuits to take the subfield results and make use of them for the full field in comparison to a full-field log/antilog-table approach.

It is also possible to perform a direct multiply in the subfield without using log/antilog look-up tables. If translation in and out of the subfield is not required, this approach has a significantly lower gate count than a full-field random-logic multiply and a slightly higher speed. However, if translation into and out of the subfield for each multiply are required, this approach results in negligible savings. This is one of the reasons that it is highly advantageous to use a quadratic-subfield representation on chip, even though this representation is different from the representation used for the incoming data.

Standard textbook algorithms require a separate calculation of a quantity known as the “formal derivative of the lambda polynomial”. This separate calculation is avoided in the decoder 10 by absorbing it into the Chien search algorithm.

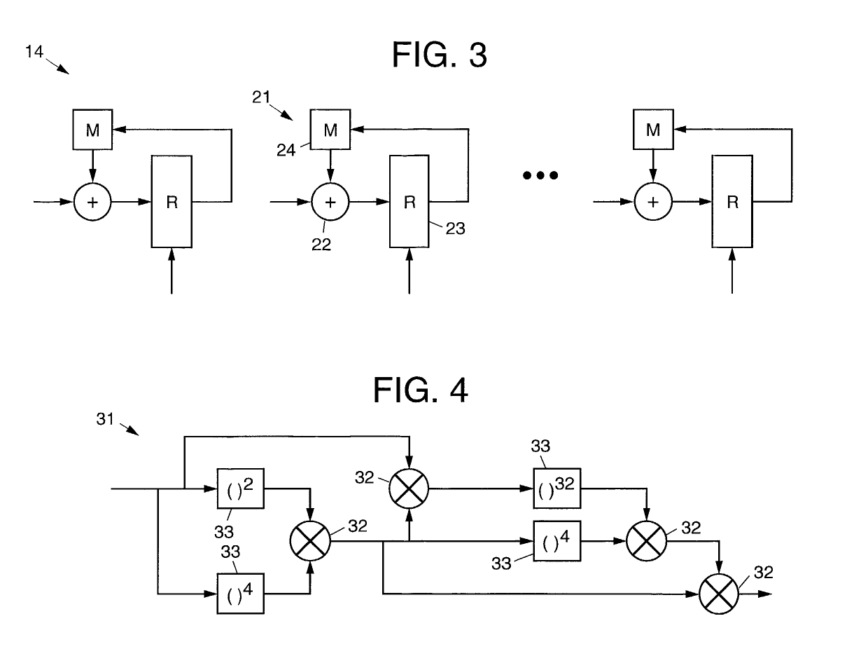

A detailed functional description of the decoder 10 is discussed below with reference to FIGS. 3-10. The descriptions and circuits shown in FIGS. 3-10 are functional. However, from the point of view of the input/output behavior, only the functional description is necessary.

The programmable decoder 10 (integrated circuit chip) is a complete decoder system implementing a number of error correcting codes. The code is programmable over a range of Reed-Solomon and binary BCH codes. The codes that are implemented in the decoder 10 are specified as follows:

1. A family of Reed-Solomon codes defined over GF(256) (i.e. Reed-Solomon codes with 8-bit symbols). The codes to be implemented in the decoder 10 have values of t=5, 8, 10, 12, 13, and 16 (where the code parameter t is the number of symbol errors correctable per Reed-Solomon codeword). For a given t, the generator polynomial g(x) is given by:

$$g ( x ) = {{⊆}^{l + 2 t - 1}}_{i = 1} ( x - {α}^{i} )$$

where α is a primitive element of the Galois Field GF(256) defined by the polynomial p(x) given in this specific embodiment by:

p(x)=x⁸+x⁴+x³+x²+1;

(p(x) is also used in this embodiment as the “field-generating” polynomial for the external off-chip Galois-field representation). The offset l is equal to 128-t, in this embodiment, resulting in a symmetrical generator polynomial. These codes have a natural block length of 255 8-bit symbols, but it is often convenient to shorten them for the purpose of simplifying the overall system design of a communications or data-storage system employing the decoder 10.

It is straightforward to implement the present invention for other field-generating polynomials p(x) simply by altering the translator and inverse translator circuits 13, 17 with no other changes at all. If the new field-generating polynomial is referred to as q(x) and the root of q(x) used to generate the off-chip Galois field is referred to as β, then it will always be the case that α is β to some integral power s, where s is commonly called the “skip” value. The existence of a non-trivial skip value is hence a consequence of using a different constant α to define g(x) than the constant β used to generate the Galois-field representation. This can occur even if p(x) and q(x) are identical but if two different roots are chosen to define g(x) and the Galois-field representation, respectively: inequality of α and β implies a non-trivial skip value.

It is also straightforward to implement the present invention for cases in which, in the generator polynomial g(x), a different α is used that is not a root of the polynomial p(x). This could occur for a variety of reasons, e.g., choice of a different polynomial q(x) to define both α and the external Galois-field representation, or continuing to use p(x) to define the external Galois-field representation but using a different polynomial q(x) to define α (the first case does not in usual terminology introduce a skip factor; the second does). Use of a different α, which is a root not of p(x) but of some other polynomial, can be accommodated simply by changes in the exclusive-OR trees used in the syndrome and Chien-Forney modules 14, 16. These changes occur whether or not the change in a leads to a “skip value” as usually conceived—it is the change in a that makes the difference.

Similarly, changes in the offset value l require only straightforward modifications in the exclusive-OR trees used in the syndrome and Chien-Forney modules 14, 16.

2. Several binary BCH codes. There are 4 BCH codes with basic block lengths of 255 bits. Specifically, the BCH codes are as follows:

(a) BCH (255,231) t=3 code with generator polynomial:

g(x)=x²⁴+x²³+x²¹+x²⁰+x¹⁹+x¹⁷+x¹⁶+x¹⁵+x¹³+x⁸+x⁷+x⁵+x⁴+x²+1

This generator polynomial is described, in standard octal notation, as

156720665

(with the equivalent binary word having a “1 ” in every location in which that power of x exists in the generator polynomial).

(b) BCH (255,230) t=3 code. This code is the expurgated version of the (255,231) code above, using only the even-weight codewords. One way to describe this code is to multiply the (255,231) generator polynomial by a factor of (x−1), resulting in the generator polynomial (in octal notation):

263161337

(c) BCH (255,223) t=4 “lengthened” code with generator polynomial (in octal notation):

75626641375

(d) BCH (255,171) t=11 code with generator polynomial (in octal notation):

15416214212342356077061630637.

The basic topology of the decoder 10 is illustrated in the block diagram shown in FIG. 2. The sequence of steps to decode a Reed-Solomon or BCH codeword is as follows:

(a) Optionally, a complete codeword may be assembled in a buffer circuit, off-chip and not a part of the decoder 10. For ultra-high speed applications, a complete decoding system may require several parallel decoder chips, and this paralleling would be handled by the buffer circuit.

(b) The codeword (data and parity) is fed to the translator circuit 13, a small asynchronous exclusive-OR tree, that translates the incoming data to the on-chip quadratic-subfield representation (for the BCH codes, no translation is required). The output of the translator 13 is fed to the syndrome circuit 14, which computes the syndromes. For both the Reed-Solomon and BCH codes that are implemented, there are 2t syndromes of 8 bits each.

(c) The syndromes are transferred to the Berlekamp-Massey module 15. The Berlekamp-Massey module 15 performs a complicated iterative algorithm, using the syndromes as input, to compute an error-locator polynomial (lambda) and an error-evaluator polynomial (omega). The output of the algorithm includes (t+1) lambda coefficients and t omega coefficients, where each coefficient is 8 bits for the Reed-Solomon codes.

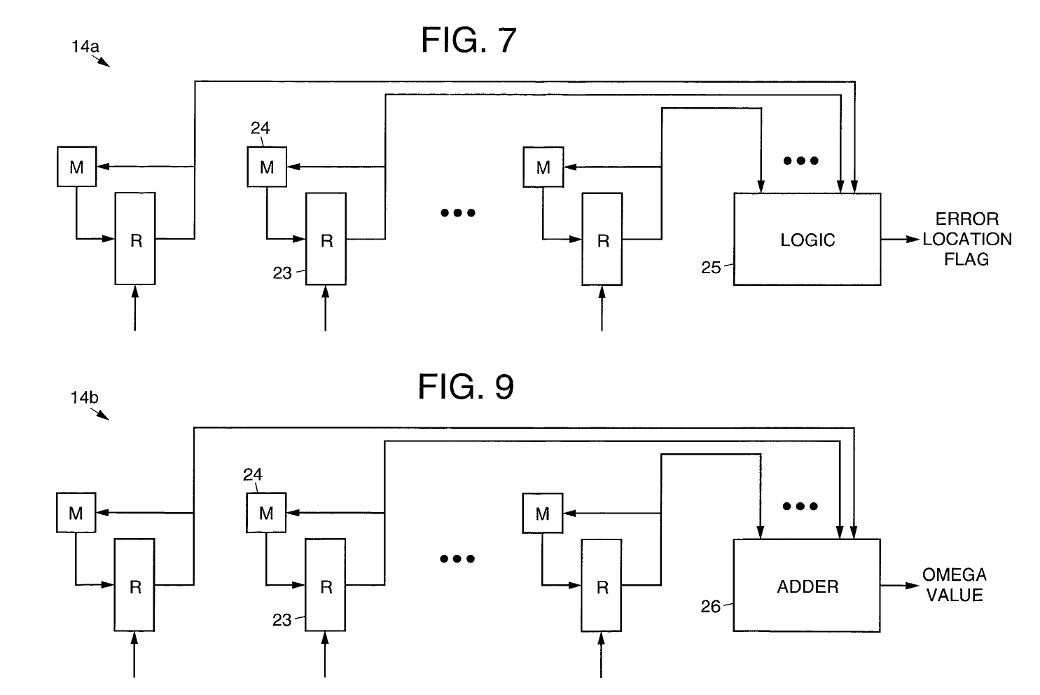

(d) The lambda coefficients and the omega coefficients are transferred to the Chien/Forney module 16. The lambda coefficients (the coefficients of the error-locator polynomial) are used in a Chien search circuit 14a (FIG. 7) that performs a Chien search, resulting in the error locations. The Chien search circuit 14a is a single-stage-feedback-shift-register-based circuit that is shifted for n cycles and whose output indicates that the symbol corresponding to that shift contains an error. The Chien search circuit 14a shown in FIG. 7 comprises a set of one-stage feedback shift registers (R) 23 whose respective outputs are fed back by way of a matrix 24, and whose respective outputs are coupled to logic 25 which outputs an error location flag. The omega coefficients (coefficients of the error-evaluator polynomial), along with a reduced form of lambda, are used in a modified Forney's algorithm to compute the error values (for the Reed-Solomon codes only). The Forney algorithm circuit includes the Galois-field divider circuit 40. The error values calculated by the Forney algorithm circuit are fed through the inverse translator circuit 17 to place them in the off-chip Galois-field representation.

The syndrome computation is performed by dividing the incoming codeword by each of the factors of the generator polynomial. This is accomplished with a set of one-stage feedback shift registers 21, as shown in FIG. 3. The one-stage feedback shift [symbol] registers 21 each comprise an adder 22 whose output is coupled through a shift register 23 to a matrix 24, whose output is summed by the adder 22 with an input. The matrices (M) 24 shown in FIG. 3 are switchable between the Reed-Solomon codes and the BCH codes.

The following gives a rough estimate of the basic circuitry in the syndrome computation register: (a) registers [symbol] 32 registers×8 flip-flops=256 flip-flops, (b) matrices [symbol] 32 matrices×average 40 XORs=1280 XORs, (c) adders [symbol] 32 adders×8 XORs=256 XORs.

The error locations are found by finding the roots of the error locator polynomial (lambda). This is commonly done by using the Chien search, implemented with the Chien search circuit 14a described below. The Chien search circuit 14a shown in FIG. 7 includes (t+1) stages, each 8 bits wide. The stages are loaded with the coefficients of the error locator polynomial lambda (from the Berlekamp-Massey algorithm), and the Chien search circuit 14a is clocked in synchronism with a byte counter. The error flag output of the Chien search circuit 14a is a “1 ” when the byte number corresponding to the byte counter is one of the bytes that is in error. Registers are provided to store the error byte numbers as they are found.

The following gives a rough estimate of the basic circuitry in the Chien search register: (a) Registers [symbol] 17 registers×8 flip-flops=136 flip-flops, (b) Matrices [symbol] 17 matrices×average 40 XORs=680 XORs, (c) Logic block [symbol] 17×8 input XOR tree=136 XORs.

The error value (i.e., which bits in the erroneous byte are in error) is computed using Forney's algorithm. When the Chien search indicates that a root of lambda has been found, the error value is determined by dividing the error evaluator polynomial omega by the value of the odd part of lambda, both evaluated at the root.

The standard textbook implementation of Forney's algorithm requires a separate calculation of a quantity known as the formal derivative of lambda: this would require a separate set of shift registers similar to those shown in FIG. 7 for the Chien search circuit 14a, except that it would only require half as many stages (because, when taking a derivative over a field of characteristic 2, the even powers disappear).

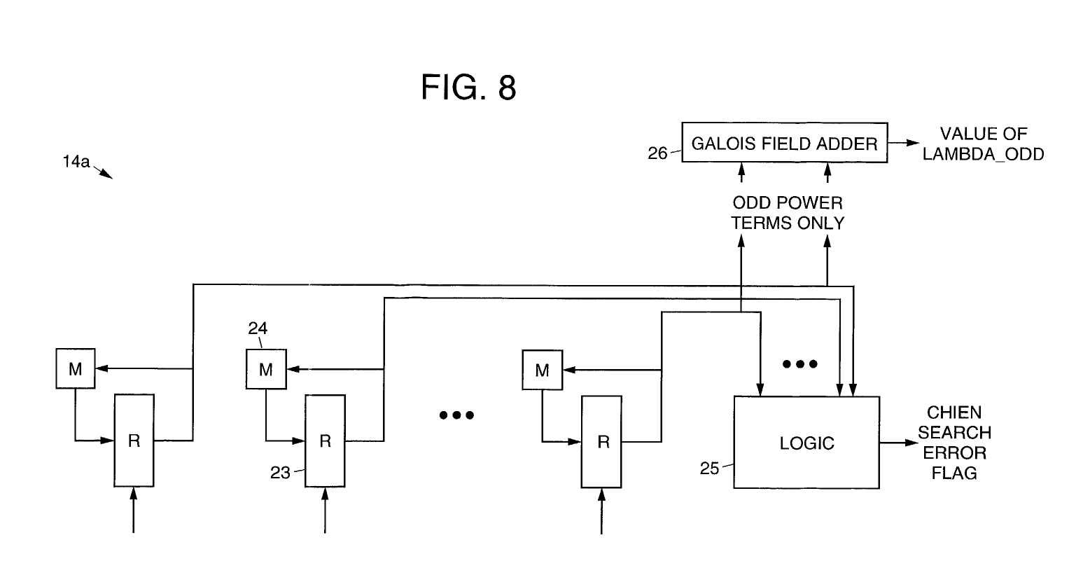

However, in the present invention, a novel method is employed to carry out Forney's algorithm, wherein, rather than requiring the formal derivative of lambda, only the sum of the odd terms of lambda are required. This may simply be accomplished by attaching a set of Galois-field adders 26 (or lambda-odd circuit 26) to the Chien search registers 23, as shown in FIG. 8. This significantly reduces circuit size and complexity. A better understanding of this technique may be found in the textbook “Reed-Solomon Codes and Their Applications”, edited by Wicker and Bhargava, IEEE Press 1994, page 96.

An omega evaluation or search circuit 14b, shown in FIG. 9, is also similar to the Chien search circuit 14a. The t registers are loaded with the omega coefficients and the circuit 14b is clocked in a manner identical to the Chien search circuit 14a of FIG. 7.

The output of the omega search circuit 14b is divided by the output of the lambda-odd circuit 26 to produce the error value, i.e., the actual bit-wise pattern of errors in a particular byte. The Galois field divider circuit 40 will be discussed in conjunction with the Berlekamp-Massey algorithm. This error value is fed through the inverse translator circuit 17 shown in FIG. 1 to convert it to the off-chip Galois-field representation and is then bit-by-bit XORed with the received byte to correct it. Registers 23 are provided to store the error byte values as they are found.

In the standard implementations of Forney's algorithm for Reed-Solomon codes with code-generator polynomial offsets (which include the codes used in this invention), it is necessary to employ an additional circuit in a Forney module to multiply by an offset-adjustment factor. In the present invention, the novel modification of Forney's algorithm which is employed does not require calculation of, or multiplication by, any offset-adjustment factor, thereby increasing speed and reducing circuit size and complexity.

The following gives a rough estimate of the basic circuitry in the omega search register: (a) Registers [symbol] 17 registers×8 flip-flops=136 flip-flops, (b) Matrices [symbol] 17 matrices×average 40 XORs=680 XORs, (c) Logic block [symbol] 17×8 input XOR tree=136 XORs. In addition, a Galois Field divider circuit 40, an 8-bit binary counter, and the registers are added to store the error locations and error values: (a) divider [symbol] 173 XORs plus 144 ANDs, (b) counter [symbol] 1 NOT plus 7 XORs plus 6 ANDs, (c) registers [symbol] 32×8 flip-flops=256 flip-flops.

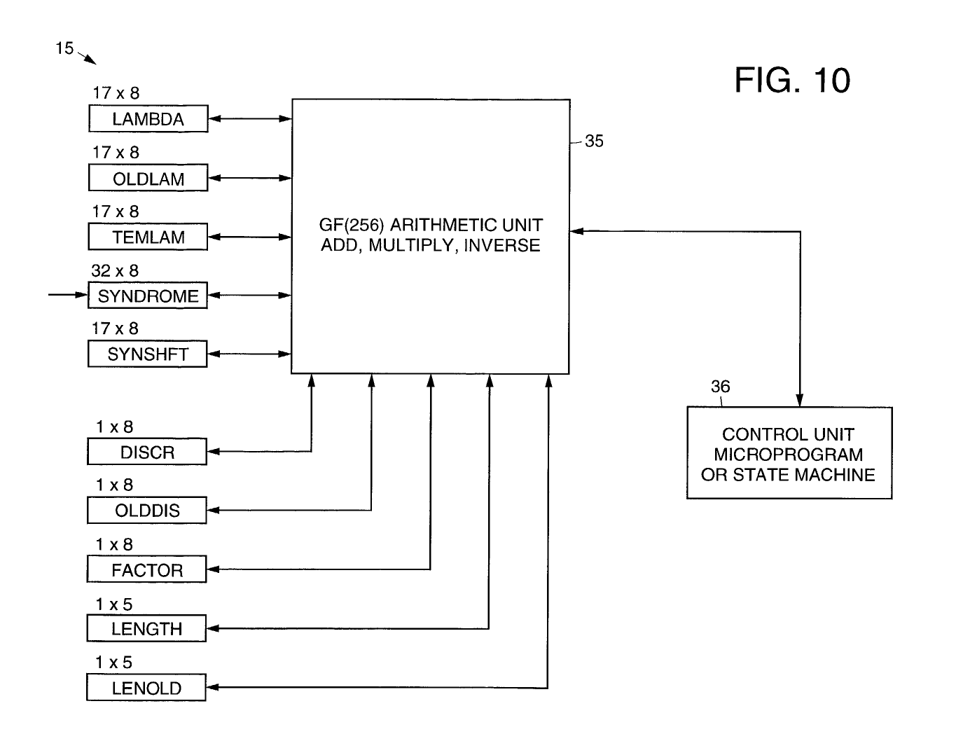

The Berlekamp-Massey algorithm is an iterative algorithm that uses algebra over a mathematical structure known as a Galois field. The Berlekamp-Massey module 15 to perform this algorithm is essentially a microprogrammed Galois field arithmetic unit. A block diagram of the Berlekamp-Massey module 15 is shown in FIG. 10.

The Berlekamp-Massey module 15 comprises a GF(256) arithmetic unit 35 coupled to a controller 36. The controller 36 may be a microprogram or a state machine, for example. The GF(256) arithmetic unit 35 has various registers coupled to it whose functions are as follows.

The registers shown in FIG. 10 are mostly scratchpad registers that store interim results during the Berlekamp-Massey algorithm. LAMBDA contains the running estimate of the error locator polynomial LAMBDA and, later in the algorithm, the running estimate of the error evaluator polynomial OMEGA. OLDLAM contains the estimate of LAMBDA from the previous iteration of the algorithm. TEMLAM is a temporary storage register for intermediate estimates of LAMBDA during the algorithm. SYNDROME contains the syndromes, initially loaded from the syndrome module. SYNSHFT is a shift register that rotates the syndromes for different iterations of the algorithm. DISCR contains the “discrepancy” that is computed at each iteration of the algorithm. OLDDIS contains the value of the “discrepancy” from the previous iteration of the algorithm. FACTOR stored the value of DISCR divided by OLDDIS, which is used to modify the updates to LAMBDA. LENGTH stores the length of LAMBDA, which represents the number of errors plus 1, and LENOLD is the length of LAMBDA from the previous iteration of the algorithm.

The mathematical operations performed by the GF(256) arithmetic unit 35 used in the Berlekamp-Massey module 15 over a Galois field include addition, multiplication, and division. Subtraction is the same as addition over a field of characteristic 2. Addition is simply a bit-by-bit exclusive-OR operation.

In a reduced-to-practice embodiment, multiplication and division are performed using gate-level circuits. If a quadratic-subfield representation were not used on the chip, the logic equations for a multiplier over GF(256) would be as follows (c(0:7) is the Galois field product of a(0:7) times b(0:7); “*” represents an AND operation; “+” represents an exclusive-OR operation; and c8 through c14 are intermediate quantities used to calculate the final answer):

c0=[(a0*b0+c14)+(c12+c13)]+c8

c1=[(a0*b1+a1*b0)+(c13+c14)]+c9

c2=[(a0*b2+a1*b1+a2*b0)+(c12+c13)]+[c8+c10]

c3=[(a0*b3+a1*b2+a2*b1+a3*b0)+(c11+c12)]+[c8+c9]

c4=[(a0*b4+a1*b3+a2*b2+a3*b1+a4*b0+c14)+c8]+[c9+c10]

c5=[(a0*b5+a1*b4+a2*b3+a3*b2+a4*b1+a5*b0)+c11]+[c9+c10]

c6=[a0*b6+a1*b5+a2*b4+a3*b3+a4*b2+a5*b1+a6*b0]+[c10+(c11+c12)]

c7=[a0*b7+a1*^{b}6+a2*b5+a3*b4+a4*b3+a5*b2+a6*b1+a7*b0]+[(c11+c12)+c13]

c8=a1*b7+a2*b6+a3*b5+a4*b4+a5*b3+a6*b2+a7*b1

c9=a2*b7+a3*b6+a4*b5+a5*b4+a6*b3+a7*b2

c10=a3*b7+a4*b6+a5*b5+a6*b4+a7*b3

c11 =a4*b7+a5*b6+a6*b5+a7*b4

c12=a5*b7+a6*b6+a7*b5

c13=a6*b7+a7*b6

c14=a7*b7

The straightforward circuit implementation of this set of logic equations comprises 64 AND gates and 77 XOR gates. While automated circuit optimization techniques can reduce this count slightly, the circuit size is still unacceptably large, especially for low-density technologies such as gallium arsenide, given that one requires a large number of these multipliers in parallel for a high-speed implementation of the Berlekamp-Massey module 15.

The solution to this problem embodied in the present invention is to use a quadratic-subfield modular multiplier circuit which is just as fast as the straightforward circuit just described but which has a significantly lower gate count. This quadratic-subfield modular multiplier circuit is used when the on-chip Galois-field representation is a quadratic-subfield representation. This is one of the major advantages of using on-chip a quadratic-subfield representation which differs from the Galois-field representation used off-chip.

A key component of the quadratic-subfield modular multiplier circuit is a subfield-multiplier module which multiplies two nybbles in the Galois subfield GF(116) to produce an output nybble as the product. The logic equations for the subfield-multiplier module of the quadratic-subfield modular multiplier circuit are as follows, and wherein, c(0:4) is the Galois field product of a(0:4) times b(0:4); “*” represents an AND operation; “+” represents an exclusive-OR operation; and c4 through c6 are intermediate quantities used to calculate the final answer:

c0=a0*b0+c4

c1=[(a0*b1+a1*b0)+c5]+c4

c2=[a0*b2+a1*b1+a2*b0+c6]+c5

c3=a0*b3+a1*b2+a2*b1+a3*b0+c6 c4=a1*b3+a2*b2+a3*b1

c5=a2*b3+a3*b2

c6=a3*b3

The subfield-multiplier module deals only with nybbles as input and output rather than with whole bytes. The primary advantage of the quadratic-subfield representation is that it makes possible this sort of breaking up of bytes into nybbles, so that the nybbles can be processed separately and in parallel. This advantage is even more telling in the case of Galois-field division.

The quadratic-subfield modular multiplier circuit also requires a simple “epsilon-multiply” module (“+” is as before; input is the nybble s(0:3), and output is the nybble t(0:3)):

t0=s0+s1

t1=s2

t2=s3

t3=s0.

The detailed logic equations for the subfield multiplier module and for the epsilon-multiply module depend in detail on the specific quadratic-subfield representation chosen. However, the way that these modules fit together to form the full quadratic-subfield modular multiplier circuit does not depend on the quadratic subfield chosen. Then, the full quadratic-subfield modular multiplier circuit is constructed as:

c1=(a1+a0)*(b1+b0)+b1*b0

c0=b1*b0+EPSILON_MULTIPLY(a1*a0)

where “*” now refers to nybble-wide multiplication using the subfield-multiplier module and where “+” now refers to bit-wise exclusive-ORing of two nybbles (i.e., “+” represents four parallel exclusive-OR gates).

The naïve gate count for the whole quadratic-subfield modular multiplier circuit is then 62 XOR gates and 48 AND gates, significantly lower than for the standard multiplier module described above which would be employed were a quadratic-subfield representation not used. As for the standard multiplier module), logic-optimization software might reduce this gate count slightly in various implementations. This physically smaller size (and correspondingly lower power consumption) of the quadratic-subfield modular multiplier circuit)) makes feasible a larger number of parallel multipliers for the Berlekamp-Massey module 15.

The other arithmetic operation required, in both the Berlekamp-Massey module 15 and the Chien-Forney module 16, is division. Division is the most difficult arithmetic operation to carry out over a Galois field, generally requiring a significantly more complicated implementation than a Galois-field multiplier. There are several generally-known methods to carry out division in a Galois field.

One obvious method is to use standard log/antilog tables, as in the multiplicative case, to carry out division: as in the case of multiplication, the size and speed of the needed ROMs can be a significant problem, especially in high-speed but low-density technologies such as gallium arsenide. A binary subtractor mod 255 is also required to perform division with this method.

A variant on this method also includes a separate table to look up the logarithm of the multiplicative inverse of the divisor rather than the divisor itself. This allows the use of a binary adder mod 255 rather than a binary mod 255 subtractor; however, the cost is a full additional ROM array. Another variant would have a separate table to directly look up the multiplicative inverse of the divisor: this could then be used as one input to any sort of Galois-field multiplier, the other input being the dividend; again, the price here is a full additional ROM.

Subfield log/antilog tables may also be used as in the multiplicative case. Again, this requires much smaller tables but a great deal of additional circuitry to go from the subfield computations to the final result for the whole full field.

The use of a table look-up technique would involve (for GF(256)) two full 64 K ROMs which store the entire full-field multiplication and division tables. However, this is very costly in terms of circuit size, especially in high-speed low-density technologies.

In these various table look-up techniques, one notes that some of the techniques require first finding the multiplicative inverse and then multiplying by the inverse, while others do not need to find the multiplicative inverse as an intermediate step. However, generally-known non-table look-up technologies for doing Galois-field division do in general require first finding the multiplicative inverse of the divisor and then, secondly, multiplying by the dividend to obtain the quotient. This two-stage approach obviously imposes serious costs in terms of speed since one must first carry out the time-consuming process of finding a multiplicative inverse before carrying out the additional task of a Galois-field multiplication.

An example of a Galois-field multiplicative-inversion module 31 that may be used in such a two-stage Galois-field divider circuit 40 is shown in FIG. 4. This power-inversion module 31 makes use of two mathematical facts about Galois fields.

First, in any Galois field with N elements, if one takes any non-zero element to the (N-2) power one gets the multiplicative inverse of the element in question. While interesting, this would naively require (N-3) multiplications, which are extremely time-consuming. However, rather than doing these (N-3) multiplications in sequence, one can make use of the basic property of exponentials that any quantity to the power pq can be calculated by first taking the exponential to the power p and then taking the result to the power q: e.g., to take the fourth power of an element, one can multiply the element by itself and then take the answer and multiply it by itself again, thereby requiring only two multiplications instead of three.

This technique allows one to reduce the number of operations to far less than (N-3) multiplies in order to get the multiplicative inverse. However, the number of multiplications required can still be substantial.

The second useful mathematical fact holds only for Galois fields for which the number of elements is a power of two—so-called fields of characteristic two, which happens to include GF(256) and most Galois fields used in practical error-correction applications. This fact is that the operation of taking any field element to a power which is itself a power of two (i.e., square, fourth power, eighth power, etc.) can be implemented by a very small and simple XOR tree without carrying out any Galois-field multiplications at all. This fact allows one to easily carry out a limited number of particular exponentiation operations which can then be used as building blocks to take the (N-2) power needed to find the multiplicative inverse.

There are a number of power-inversion Galois-field multiplicative inversion modules 31 that may be straightforwardly designed based on these two principles. FIG. 4 is a simple example for GF(256). This power-inversion module 31 requires four separate full-field Galois-field multipliers 32, as well as several power-of-two exponentiation modules 33 connected as shown in FIG. 4 (the power-of-two exponentiation modules 32 are very small exclusive-OR trees; nearly all of the gate count is in the four multipliers 32). In addition, another multiplier is required to carry out the final multiplication with the dividend.

Of course, if one re-used one or more of the multipliers 32, one could have fewer than four multipliers 32. However, this can become quite complicated in terms of control circuitry, data flow, and timing.

The gate count for a Galois-field divider circuit 40 using the power-inversion module 31 presented in FIG. 4 and an additional multiplier 32 to multiply by the dividend, if everything is done in a standard (non-subfield) Galois-field representation using standard non-subfield multipliers, is 438 XOR gates and 320 AND gates. The gate delay is 31 XOR gate delays and 5 AND gate delays. This is very big and very slow. In the present invention, a novel method of performing Galois-field division is implemented, a subfield-power integrated Galois-field divider circuit 40. This method does not use table look-up, and it is not necessary to carry out a multiplicative inversion before multiplying by the dividend. The gate count for the divider circuit 40 is 144 AND gates and 173 XOR gates; the total gate delay is 3 AND gate delays and 11 XOR gate delays: i.e., this is more than twice as fast and less than half the size of the previously described divider when using the power-inversion method.

The implementation of the subfield-power integrated Galois-field divider circuit 40 is shown in FIG. 6. Just as the use of a quadratic-subfield representation allows creation of a quadratic-subfield modular multiplier that handles the two nybbles of a single byte as separate quantities that can be operated on in parallel, so also the subfield-power integrated divider circuit 40 processes nybbles separately. Most of the implemented circuit includes the same subfield multiply modules (or slight variations thereof) used in the quadratic-subfield modular multiplier as described above.

One key feature of the subfield-power integrated divider circuit 40 is the use of power-inversion methods to invert a single nybble within the subfield. As is shown in FIG. 6, this involves the square, fourth power, and eighth power modules 41, 42, 43 and multipliers 44 which take the product of the output of these three modules 44. This utilizes the mathematical fact that the fourteenth power of any element of the subfield, GF(16), is the inverse of that element. Thus, the subfield-power integrated divider circuit 40 utilizes power-inversion techniques, but only for one nybble which is an intermediate result of the calculation, not for any byte as a whole: in this respect, it differs from the standard power-inversion technique presented in FIG. 4.

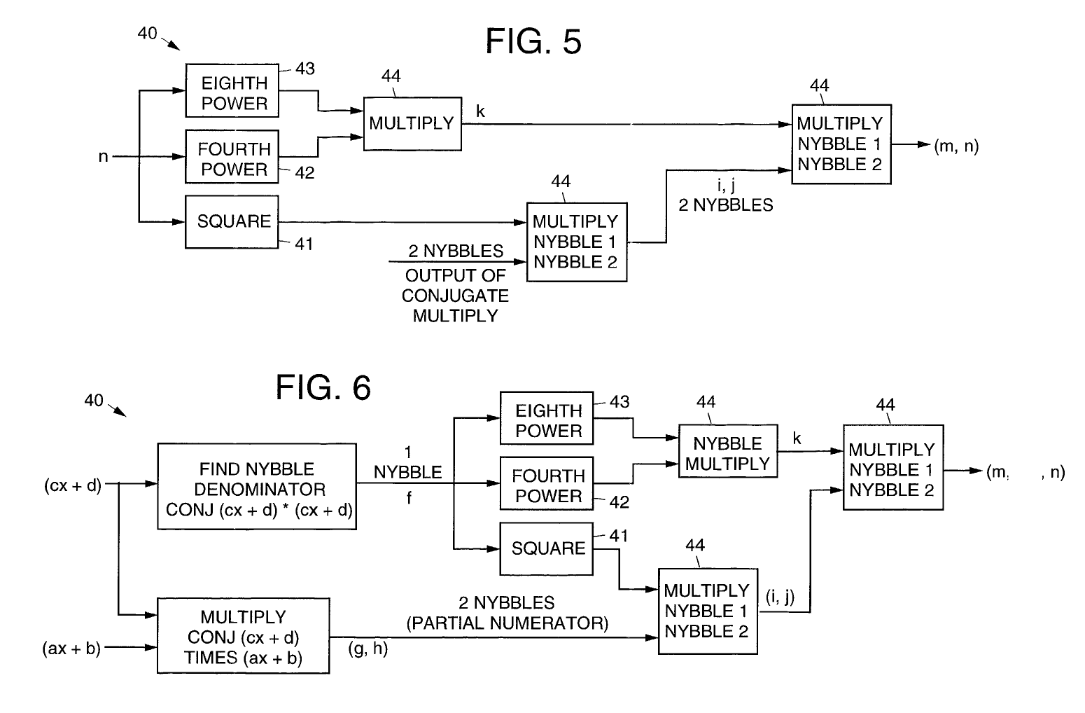

Furthermore, as shown in FIG. 6, the output of the squaring module 41 is not immediately multiplied by the outputs of the fourth power and eighth power modules 42, 43 as would be done if the multiplicative inverse were simply calculated. For comparison, FIG. 5 separates out the relevant part of the subfield-power integrated divider circuit 40. If the multiplier 44 immediately following the squaring module 41 were removed, one would then have a nybble inversion module. Rather, the output of the squaring module 41 multiplies the output of a module that did a preliminary multiply on the input dividend (ax+b), while, at the same time and in parallel, the outputs of the fourth and eighth power modules 42, 43 are multiplied together. The result is that the multiplicative inverse is not actually calculated. In effect, the dividend is multiplied by the multiplicative inverse of the divisor at a point in time at the beginning of the calculation of the multiplicative inverse of the divider circuit 40. In this manner, the process of multiplicative inversion and multiplication are intimately integrated so that the multiplication, in effect, costs no time at all. To carry out a full division takes exactly the same amount of time with this technique as simply to carry out a multiplicative inversion.

This “zero-time multiply feature,” created by the intimate integration between the submodules which would normally separately and independently carry out multiplicative inversion and, later serially, full-field multiplication is a unique feature of the present invention. This parallelism and modular cross-connections are possible because it is done in the quadratic-subfield representation which naturally handles separate nybbles in parallel.

The following gives a rough estimate of the basic circuitry in the Berlekamp-Massey module 15: (a) Registers [symbol] 834 flip-flops, (a) 17 parallel multipliers [symbol] 17×(62 XORs+48 ANDs)=1054 XORs+816 ANDs, (b) Power-subfield divider [symbol] 173 XORs+144 ANDs, (c) Microprogram storageZ,900 estimated 64×24 RAM, and (d) ALU control circuitry [symbol] ≈2000 gates.

Inter-module communication and timing will now be discussed. The method and timing of the transfer of syndromes and error locator coefficients between the various modules of the decoder 10 is a significant issue. The sequence of decoding operations for a single codeword (BCH or Reed-Solomon) is as follows:

(a) As the bytes (or bits) of the codeword are received, they are applied to the syndrome computation circuit 14 after going through the translator circuit 13. In this way the syndromes are being computed in real time as the codeword is being received. (In terms of communication and timing issues, the translator circuit 13 should be viewed as part of the syndrome module 14, although it is conceptually distinct.)

(b) Immediately after the last bit or byte of a codeword has been clocked into the syndrome computation circuit 14, this circuit contains the actual syndromes. These syndromes are then transferred to the Berlekamp-Massey module 15. This transfer takes place before the syndrome computation circuit 14 begins computation on the next codeword, or alternatively there must be a register to hold the syndromes for transfer. The maximum number of bits of syndrome that are transferred is set by the t=16 Reed-Solomon code, for which there are 32 syndromes of 8 bits each for a total of 256 bits.

(c) The Berlekamp-Massey module 15 performs the iterative Berlekamp-Massey decoding algorithm to compute the coefficients of the error locator polynomial (Λ) and the error evaluator polynomial (Ω).

(d) The coefficients of the error locator polynomial and the error evaluator polynomial are transferred to the Chien/Forney module 16. There are a maximum of 17 error locator coefficients of 8 bits each and 16 error evaluator coefficients of 8 bits each (set by the t=16 Reed-Solomon code). These bits are all transferred before the Berlekamp-Massey module 15 starts on the next codeword.

(e) The Chien/Forney module 16 performs the Chien search and Forney's algorithm. The shift registers that perform these algorithms are clocked in synchronism with a byte counter, the error values go through the inverse translator circuit 17, and the erroneous byte locations and values are stored. In terms of communication and timing issues, the inverse translator circuit 17 should be viewed as part of the Chien/Forney module, although it is conceptually distinct.

(f) The erroneous bytes are read out and corrected by exclusive-ORing the error value with the codeword byte.

Thus, a programmable, systolic, Reed-Solomon BCH error correction decoder implemented as an integrated circuit has been disclosed. It is to be understood that the described embodiment is merely illustrative of some of the many specific embodiments that represent applications of the principles of the present invention. Clearly, numerous and other arrangements can be readily devised by those skilled in the art without departing from the scope of the invention.

What is claimed is:

1. A programmable, architecturally-systolic, Reed-Solomon BCH error correction decoder for decoding a predetermined number of Reed-Solomon and BCH codes, said decoder comprising:
a translator circuit for receiving one of the predetermined number of Reed-Solomon and BCH codes that each have predetermined external Galois-field representations and for translating the external Galois-field representation of the received code into an internal Galois-field representation;
a syndrome computation module for calculating syndromes comprising intermediate values required to find error locations and values,
a Berlekamp-Massey computation module that implements a Berlekamp-Massey algorithm that converts the syndromes to intermediate results comprising lambda and omega polynomials;
a Chien-Forney module comprising modified Chien-search and Forney algorithms to calculate actual error locations and error values that correspond to an error-corrected code; and
an inverse translator circuit for translating the internal Galois-field representation of the error-corrected code into the external Galois-field representation.

2. The decoder recited in claim 1 wherein the internal Galois-field representation is a quadratic subfield representation that is a different representation from the representation employed by data input to the decoder.

3. The decoder recited in claim 1 wherein the Berlekamp-Massey module carries out repeated dot product calculations between vectors with up to T+1 components using Galois-field arithmetic, where T is the error correcting capability of the code.

4. The decoder recited in claim 1 wherein the Berlekamp-Massey computation module includes parallel quadratic-subfield modular multipliers that are used to carry out each dot product calculation in a single step.

5. The decoder recited in claim 1 wherein the Berlekamp-Massey computation module and the Chien-Forney module each include a quadratic-subfield-power integrated divider that carries out Galois-field division in a quadratic-subfield representation.

6. The decoder recited in claim 1 wherein the Chien-Forney module comprises an offset-adjustment-free Forney module that carries out Forney's algorithm without calculating a formal derivative of the lambda polynomial and without calculating an offset-adjustment factor for Reed-Solomon codes with offsets in the code-generator polynomial.

7. The decoder recited in claim 1 wherein the clocks controlling the syndrome computation module, the Berlekamp-Massey computation module, and the Chien-Forney module are separate and free-running clocks requiring no fixed phase relationship, to allow maximum speed and flexibility for the clocks of each module.

8. The decoder recited in claim 1 wherein configuration information travels systolically with the data from the syndrome module to the Berlekamp-Massey module and from the Berlekamp-Massey module to the Chien-Forney module, providing for switching among different codes and among codes of different degrees of shortening.

9. The decoder recited in claim 1 wherein dual-mode operation for BCH codes allows two simultaneous BCH data blocks to be processed at once.

10. The decoder recited in claim 1 wherein internal registers and computation circuitry are shared among different code types, binary BCH and non-binary Reed-Solomon, thereby reducing total gate count.

11. The decoder recited in claim 1 wherein alterations solely in exclusive-OR trees of the translator and inverse translator circuits enable the decoder to decode Reed-Solomon codes using any Galois-field representation linearly related to standard representations, including representations generated by a field-generator polynomial and standard subfield representations.

12. The decoder recited in claim 1 wherein alterations solely in exclusive-OR trees of the syndrome module and the Chien-Forney module enable the decoder to decode Reed-Solomon codes using code-generator polynomials having any offset and skip values, including standard code-generator polynomials.

13. The decoder recited in claim 1 wherein logic checks in the Berlekamp-Massey module on the length of the lambda polynomial and in the Chien-Forney module on the number of errors detected are sufficient to detect all undetectable error patterns that are mathematically possible to detect.

14. A method for decoding a predetermined number of Reed-Solomon and BCH codes comprising the steps of:
translating one of a predetermined number of Reed-Solomon and BCH codes that each have predetermined external Galois-field representations into an internal Galois-field representation;
calculating syndromes comprising intermediate values required to find error locations and values;
converting the syndromes to intermediate results comprising lambda and omega polynomials using a Berlekamp-Massey algorithm;
calculating actual error locations and error values that correspond to an error-corrected code using Chien-search and Forney algorithms; and
translating the internal Galois-field representation of the error-corrected code into the external Galois-field representation.

15. The method recited in claim 14 wherein the internal Galois-field representation is a quadratic subfield representation.

16. The method recited in claim 14 wherein the step of converting the syndromes to intermediate results comprises the steps of performing repeated dot product calculations between vectors with up to T+1 components using Galois-field arithmetic, where T is the error correcting capability of the code.

17. The method recited in claim 14 wherein alterations solely in exclusive-OR trees enable decoding of Reed-Solomon codes using any Galois-field representation linearly related to standard representations, including representations generated by a field-generator polynomial and standard subfield representations.

18. The method recited in claim 14 wherein alterations solely in exclusive-OR trees enable decoding of Reed-Solomon codes using code-generator polynomials having any offset and skip values, including standard code-generator polynomials.

19. The method recited in claim 14 wherein logic checks on the length of the lambda polynomial and on the number of errors detected are sufficient to detect all undetectable error patterns that are mathematically possible to detect.
